(19) United States
(12) Patent Application Publication
(10) Pub. No.: US 2024/0397604 A1
(43) Pub. Date: Nov. 28, 2024

(54) GRAPHENE INTEGRATED CORE AND ASSOCIATED METHODS FOR THERMAL MANAGEMENT WITHIN PRINTED CIRCUIT BOARDS

(71) Applicants: NVIDIA CORPORATION, Santa Clara, CA (US); BAR ILAN UNIVERSITY, Ramat Gan (IL)

(72) Inventors: Oren STEINBERG, Tal Shahar (IL); Elad MENTOVICH, Tel Aviv (IL); Sima BUCHBINDER, Haifa (IL); Boaz ATIAS, Maale Adumim (IL); Ori AZULAY, Moshav Yatzitz (IL); Yosi BEN-NAIM, Eilat (IL); Adi LEVI, Rosh HaAyin (IL); Doron NAVEH, Petah-Tikva (IL); Elia Olga KRONGAUZ, Rehovot (IL)

(73) Assignees: NVIDIA CORPORATION, Santa Clara, CA (US); BAR ILAN UNIVERSITY, Ramat Gan (IL)

(21) Appl. No.: 18/200,314

(22) Filed: May 22, 2023

(51) Int. Cl. H05K 1/02; H05K 1/03

(52) U.S. Cl. CPC H05K 1/0204; H05K 1/0353; H05K 2201/0145; H05K 2201/0154

(57) ABSTRACT

Methods of forming a graphene integrated core for making a printed circuit board (PCB) having enhanced thermal management properties are disclosed. The methods include providing a core body having a core body length and applying a graphene multi-layer to the core body to form a laminated stack, where the graphene multi-layer has a graphene multi-layer length that is shorter than the core body length. At least one conductive layer may be applied to the laminated stack. The graphene multi-layer may be disposed within the graphene integrated core such that the graphene multi-layer is electrically insulated from the at least one conductive layer. Corresponding graphene integrated cores having a graphene multi-layer that is disposed within the graphene integrated core such that the graphene multi-layer is electrically insulated from the at least one conductive layer are also described.

### TECHNOLOGICAL FIELD

Embodiments of the present invention relate generally to laminated structures for printed circuit boards (PCBs) and methods for integrating graphene therein.

### BACKGROUND

A PCB is a laminated structure of conductive and insulating layers that is used to support electronic components and to provide electrical connections and open circuits between electrical terminals. In general, each of the conductive layers comprises a pattern of electrical pathways or traces that provides electrical connections on that conductive layer. In addition, vias, or plated through-holes, may be provided to allow electrical interconnection between different conductive layers.

The conductive layers may, for example, comprise metal sheets (e.g., copper foil) that are applied to the insulating layers, and this laminated structure may be referred to as the “core” of the PCB. The metal sheets can be etched into separate conducting lines (traces). As the demand for higher bandwidth increases, so too does the demand for higher frequency performance. As current loads on a PCB increase, however, the components of the PCB can generate heat. Depending on the design or layout of the PCB, heat may accumulate in certain locations, which can lead to less than optimal component performance and, in some cases, can lead to component failure and/or a shortened lifespan of the PCB.

### BRIEF SUMMARY

Embodiments of the present invention provide an improved core for PCBs that integrates graphene within the core structure for better thermal management, without impairing the electrical performance of PCB, as well as associated methods for forming an integrated multi-layer graphene core.

In some embodiments, a method of forming a graphene integrated core is provided, where the method comprises providing a core body having a core body length; applying a graphene multi-layer to the core body to form a laminated stack, and applying at least one conductive layer to the laminated stack. The graphene multi-layer may have a graphene multi-layer length that is shorter than the core body length. The graphene multi-layer may be disposed within the graphene integrated core such that the graphene multi-layer is electrically insulated from the at least one conductive layer.

In some embodiments, applying a graphene multi-layer to the core body to form a laminated stack may comprise forming a graphene-dielectric structure, and the method may further comprise assembling multiple graphene-dielectric structures to form the laminated stack. In some cases, assembling multiple graphene-dielectric structures may comprise applying a connecting layer between adjacent graphene-dielectric structures. At least a portion of the connecting layer may be disposed between the graphene multi-layer and the at least one conductive layer. In some cases, the laminated stack may be patterned.

In some embodiments, applying a graphene multi-layer to the core body to form a laminated stack may comprise applying a first graphene multi-layer to a first core body to form a first graphene-dielectric structure; individually patterning the first graphene-dielectric structure; applying a second graphene multi-layer to a second core body to form a second graphene-dielectric structure; individually patterning the second graphene-dielectric structure; assembling the first and second graphene-dielectric structures to form the laminated stack; and applying a final pattern to the laminated stack.

Applying a graphene multi-layer to the core body to form a laminated stack may, in some cases, comprises growing graphene on a growth substrate to form the graphene multi-layer; patterning the graphene multi-layer; applying the core body to the patterned graphene multi-layer; and removing the growth substrate.

In some embodiments, the graphene multi-layer may be a plurality of graphene multi-layers, wherein each graphene multi-layer is spaced from adjacent graphene multi-layers. The plurality of graphene multi-layers may comprise n graphene multi-layers and n+1 connecting layers adjacent each graphene multi-layer, wherein the connecting layers secure the plurality of graphene multi-layers with respect to each other.

In some embodiments, the method may further comprise defining a via through the graphene integrated core, wherein applying the at least one conductive layer to the laminated stack comprises applying the at least one conductive layer to an inner surface of the via.

In other embodiments, a graphene integrated core may be provided that comprises a core body having a core body length; a graphene multi-layer applied to the core body to form a laminated stack; and at least one conductive layer. The graphene multi-layer may have a graphene multi-layer length that is shorter than the core body length, and the graphene multi-layer may be disposed within the graphene integrated core such that the graphene multi-layer is electrically insulated from the at least one conductive layer.

In some embodiments, the graphene multi-layer may be a first graphene multi-layer, and the graphene integrated core may further comprise a second graphene multi-layer, wherein the second graphene multi-layer is spaced from the first graphene multi-layer. The first graphene multi-layer may be in a different plane than the second graphene multi-layer in some cases. In other cases, the first graphene multi-layer may be in the same plane as the second graphene multi-layer.

The graphene multi-layer and the core body may, in some cases, form a graphene-dielectric structure. The graphene integrated core may further comprise multiple graphene-dielectric structures having a connecting layer disposed between adjacent graphene-dielectric structures. In some embodiments, at least a portion of the connecting layer may be disposed between the graphene multi-layer and the at least one conductive layer.

In some embodiments, the at least one conductive layer may be disposed on an outer surface of the graphene integrated core. The at least one conductive layer may, in some cases, be disposed on an inner surface of a via formed through the graphene integrated core.

In some embodiments, the core body may comprise at least one of polyimide, polyester, polyurethane, bismaleimide triazine (BT), cyanate ester, fused silica, woven glass, fiberglass, microfiber glass, epoxy resin, phenol compounds, polytetrafluoroethylene (PTFE), low density polyethylene (LDPE), high density polyethylene (HDPE), polyethylene terephthalate (PET), thermoplastic polyurethane (TPU), or ceramic material.

The graphene multi-layer may, in some cases, have a thickness in the range of approximately one nanometer to approximately two microns.

The above summary is provided merely for purposes of summarizing some example embodiments to provide a basic understanding of some aspects of the present disclosure. Accordingly, it will be appreciated that the above-described embodiments are merely examples and should not be construed to narrow the scope or spirit of the disclosure in any way. It will be appreciated that the scope of the present disclosure encompasses many potential embodiments in addition to those here summarized, some of which will be further described below.

### BRIEF DESCRIPTION OF THE DRAWINGS

Having thus described the disclosure in general terms, reference will now be made to the accompanying drawings, which are not necessarily drawn to scale. The components illustrated in the figures may or may not be present in certain embodiments described herein. Some embodiments may include fewer (or more) components than those shown in the figures.

FIGS. 1A-1C illustrate cross-sections of a lamination stack incorporating graphene multi-layers;

FIGS. 2A-2C illustrate top plan views of the lamination stack of FIGS. 1A-1C;

FIG. 3 illustrates a cross-sectional side-view of an integrated multi-layer graphene core in accordance with one or more embodiments of the present invention;

FIG. 4 illustrates a cross-sectional side-view of an integrated multi-layer graphene core having multiple graphene multi-layers in the same plane and in different planes in accordance with one or more embodiments of the present invention;

FIG. 5 illustrates a cross-sectional side-view of a graphene multi-layer structure having a plurality of graphene multi-layers in accordance with one or more embodiments of the present invention;

FIG. 6 provides an example flowchart of a process for forming a graphene integrated core in accordance with one or more embodiments of the present invention;

FIG. 7 provides an example flowchart of a process for assembling multiple graphene-dielectric structures to form a laminated stack that is patterned for forming a graphene integrated core in accordance with one or more embodiments of the present invention;

FIG. 7A illustrates a cross-sectional side view of a graphene-dielectric structure in accordance with one or more embodiments of the present invention;

FIG. 7B illustrates a cross-sectional side view of a lamination stack formed by assembling multiple graphene-dielectric structures of FIG. 7A in accordance with one or more embodiments of the present invention;

FIG. 8 provides an example flowchart of a process for forming a graphene integrated core by individually patterning first and second graphene-dielectric structures in accordance with one or more embodiments of the present invention;

FIGS. 8A and 8B illustrate partial cross-sectional side views of a graphene-dielectric structure for forming a lamination stack in accordance with one or more embodiments of the present invention;

FIG. 8C illustrates a top plan view of the graphene-dielectric structure of FIG. 8B;

FIGS. 8D-8E illustrate partial cross-sectional side views of a lamination stack formed using the graphene-dielectric structure of FIGS. 8B and 8C in accordance with one or more embodiments of the present invention;

FIG. 8F illustrates a partial cross-sectional side view of a graphene integrated core formed using the lamination stack of FIG. 8E;

FIG. 9 provides an example flowchart of part of a process for forming a graphene integrated core by individually patterning a graphene multi-layer grown on a growth substrate in accordance with one or more embodiments of the present invention; and

FIGS. 9A-9C illustrate cross-sectional side views of a graphene multi-layer grown on a growth substrate and applied to a core body in accordance with one or more embodiments of the present invention.

### DETAILED DESCRIPTION

Example embodiments will now be described more fully hereinafter with reference to the accompanying drawings, in which some, but not all, embodiments are shown. Indeed, the embodiments may take many different forms and should not be construed as limited to the embodiments set forth herein; rather, these embodiments are provided so that this disclosure will satisfy applicable legal requirements. Like reference numerals refer to like elements throughout. The terms “exemplary” and “example” as may be used herein are not provided to convey any qualitative assessment, but instead merely to convey an illustration of an example. As used herein, terms such as “front,” “rear,” “top,” “bottom,” “inside,” “outside,” “inner,” “outer,” etc. are used for explanatory purposes in the examples provided below to describe the relative position of certain components or portions of components. Furthermore, as would be evident to one of ordinary skill in the art in light of the present disclosure, the terms “substantially” and “approximately” indicate that the referenced element or associated description is accurate to within applicable engineering tolerances. Thus, use of any such terms should not be taken to limit the spirit and scope of embodiments of the present invention. Moreover, while the term “metallic” is used herein for ease of explanation, it is understood that, in some cases, the metallic material is any suitable electrically conductive material, such as a ceramic or semiconductor material.

Graphene, an allotrope of carbon, consists of a single layer of atoms (one atomic layer of graphite) arranged in a two-dimensional honeycomb lattice nanostructure. It is considered a semi-metal having unusual electronic properties that may be described by theories for massless relativistic particles. One characteristic of graphene (and graphite, which generally refers to the commonly found, naturally-occurring mineral that is composed of many layers of graphene) is that it conducts heat and electricity very efficiently along its plane. In addition, it has exceptionally high tensile strength, electrical conductivity, and transparency. For ease of explanation, embodiments of the invention are described herein as including graphene multi-layers. As used herein, a graphene multi-layer is a layer made up of multiple graphene layers, such as 2 layers of graphene, 100 layers of graphene, 1,000 layers of graphene, 10,000 layers of graphene, one million layers of graphene, and so on.

A lamination stack, generally, is a structure formed by layers of materials (e.g., conductive and non-conductive) that are heated, pressed, and/or further processed to form a PCB. For example, such materials may include a non-conductive material (e.g., the core) possessing dielectric properties, an adhesive layer, and a conductive metal, such as copper (e.g., copper foil). The lamination stack may then be laminated (i.e., heated and/or pressurized under vacuum or controlled gas atmosphere) to solidify a bond between the layers of material to create the structure of the PCB. In some aspects of the present invention, heat may be applied to the base of the lamination stack (e.g., from below the lamination stack), applied to the top of the lamination stack (e.g., from a heat-source placed above the lamination stack), or applied to surround the lamination stack (e.g., from an oven chamber heating the lamination stack from multiple sides). The metal material (e.g., copper) may then be etched to create the electrically conductive trace of the PCB.

According to embodiments of the present invention, multi-layers of graphene are incorporated into the core to produce an integrated core structure that can be used to form a PCB having improved performance and improved heat management. By adding one or more multi-layers of graphene to the core laminate, the resulting PCB is imbued with improved properties over conventional lamination stacks. For instance, the incorporation of graphene multi-layers may serve to improve heat management because of its high heat conductivity properties, promote higher electrical conductivity, and allow higher electron mobility, without having to make allowances for thickness on a PCB, as graphene is extremely thin as a monolayer.

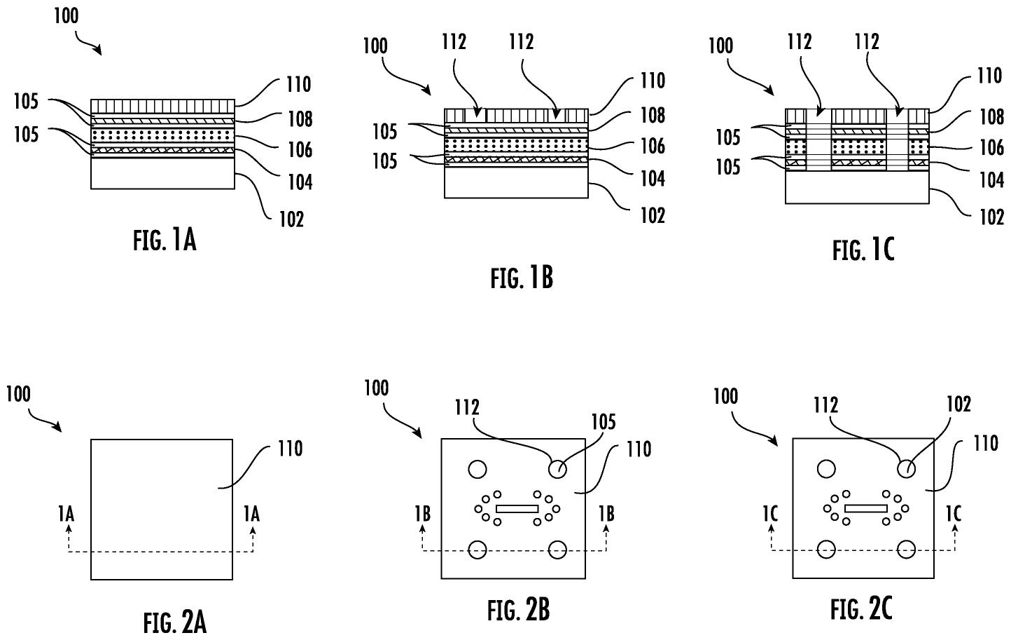

With reference to FIGS. 1A-1C and FIGS. 2A-2C, a method of forming a PCB using a graphene integrated core laminate structure according to embodiments of the present invention is illustrated. For example, in FIG. 1A, a side view of a laminate structure 100 is shown that includes a core material 102, a first multi-layer of graphene 104, a metal layer 106 (such as copper), a second multi-layer of graphene 108, and a protective layer 110. The protective layer 110 may, for example, be any protective layer that can be patterned, such as a photoresist, another lithographic resist (photo, heat, electrical), or a protective film that can be patterned by mechanical or laser scribing. In some cases, a connecting layer (e.g., a dielectric glue) or other dielectric layer 105 is disposed between adjacent layers of the laminate structure 100. The dielectric layers 105 may serve to separate and insulate from each other the conductive layers of the laminate structure 100, such as the first and second graphene multi-layers 104, 108 and/or the metal layer 106. FIG. 2A shows a top view of the laminate structure 100 of FIG. 1A. As illustrated, viewing the laminate structure 100 from the top, only the protective layer 110 is seen. In a case where the protective layer 110 is a photoresist (e.g., a light-sensitive material, exposure to light or another focused energy source such as an electron beam will change the layer's solubility or sensitivity with respect to a developer, thereby allowing the layer to be patterned. In other cases, however, the protective layer 110 may be a thermal release film or sheet or a polymer such as polycarbonate or other suitably rigid polymer.

Turning to FIGS. 1B and 2B, a patterned mask (not shown) may be applied adjacent the protective layer 110. In a case where the protective layer 110 is a photoresist layer, when light is applied the mask, which is disposed between the light source and the photoresist layer, the photoresist material in only certain areas not protected by the mask will change its solubility. In other areas, the patterned mask will block the light, such that no change in the photoresist material occurs in the regions underlying the mask. The mask may then be removed, and a solvent or developer can be applied to the surface of the photoresist. Because the solubility of portions of the photoresist have been changed, those portions will be dissolved by the solvent or developer, forming gaps 112 in the protective layer 110 and exposing the dielectric layer 105 beneath, as shown in FIGS. 1B (side view) and 2B (top view). In some cases (e.g., where a negative photoresist is used), the application of light will serve to strengthen the unmasked regions of the photoresist material. Thus, in these cases, the application of the solvent will dissolve or wear away only the portions of the protective layer 110 that were not exposed to the light. Accordingly, various processes may be used to form a pattern in the protective layer 110, such as photolithography, electron beam lithography, photoengraving, laser etching, computer numerical control (CNC) router, and/or other mechanical means.

With the gaps 112 formed in the photoresist layer 110, the first and second graphene multi-layers 104, 108, the metal layer 106, and any intervening dielectric layers 105 may be selectively removed (e.g., reactive ion etching, ion milling, laser ablation, or other methods) to achieve the same pattern of the gaps 112 in the protective layer 110, as shown in FIGS. 1C and 2C.

Depending on the type of protective layer 110 and mechanism for patterning that is selected, an additional protective layer, which may be a photoresist dry film, a thermal release film, or any other material layer that can serve to protect the prepatterned circuit, may be applied to the top and bottom of the laminate structure 100 in preparation for a drilling procedure. Similarly, in some cases various ones of the layers 110, 104, 105, and/or 106 may be included or not included, depending on the particular circuit being designed, the materials used, and the patterning processes selected for making the circuit. Such additional protective layers may, for example, serve to shield and protect the intermediate layers (e.g., one or more of the core material 102, the first multi-layer of graphene 104, the metal layer 106, the second multi-layer of graphene 108, the intervening dielectric layers 105, and/or the protective layer 110 in the depicted embodiment) as vias or other through-holes are drilled through the combined laminate structure. Further processing of the layered structure, such as metallic plating and/or removal of superfluous protective layers, may take place, depending on the type of circuit and its intended application.

In applications in which the laminate structure is plated with a metal layer, any contact between the first or second graphene multi-layers 104, 108 (which are electrically conductive) with the outer metallic layer may cause electricity to be conducted therethrough, which may cause a short and/or may otherwise be undesirable for proper functioning of the finished PCB. As such, embodiments of the invention provide a graphene integrated core in which the graphene multi-layers are disposed with respect to the core body such that the graphene multi-layers layers are electrically insulated from the metallic or otherwise electrically conductive layers. In this way, graphene multi-layers can be incorporated into the laminate structure to impart the beneficial characteristics of graphene described above, but without impeding the proper function of the resulting PCB. Corresponding methods of manufacturing the graphene integrated core is also described below.

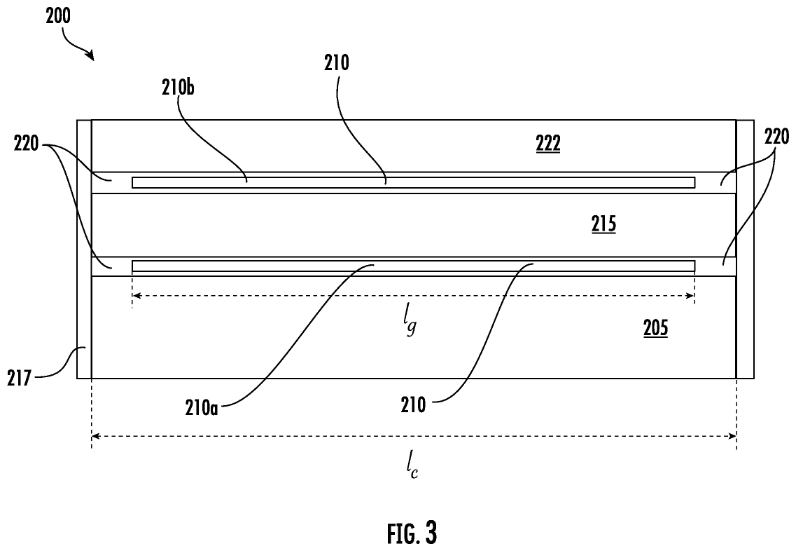

Turning now to FIG. 3, a graphene integrated core 200 is shown according to embodiments of the invention. The graphene integrated core 200 comprises a core body 205 having a core body length l_{c} and a graphene multi-layer 210 disposed with respect to the core body to form the graphene integrated core 200. The graphene multi-layer 210, which may be a plurality of graphene layers (e.g., multiple atomic layers of graphene) may have a graphene multi-layer length l_{g} that is shorter than the core body length l_{c}. The graphene integrated core 200 may further comprise at least one metallic layer 217, such as a layer of copper, that is applied to an outer surface of the graphene integrated core (metallic layer 217 in the depicted embodiment). In some cases, for example, the at least one metallic layer may be applied to an inner surface of a via 225 formed through the graphene integrated core 200, as shown in FIG. 3. The graphene integrated core 200 may, in some cases, further comprise at least one insulative layer 215. In other embodiments, however, additional insulative and/or metallic layers, similar to the layer 215 shown in FIG. 3, may be included within the graphene integrated core 200.

In some cases, other additional layers 222, such as a photoresist layer or a protective coating, may also be included in the graphene integrated core 200. Because the graphene multi-layer length l_{g} is shorter than the core body length l_{c}, the edges of the graphene multi-layer(s) 210 are spaced from the metallic layer(s) 217 and do not make contact. Accordingly, the graphene multi-layer 210 is disposed within the graphene integrated core 200 such that the graphene multi-layer 210 is electrically insulated from the at least one metallic layer 217.

In some cases, prepreg (e.g., a composite material such as carbon, graphite, or glass fiber that is “pre-impregnated” with resins and then cured to form a dielectric material) or a dielectric glue may be used to laminate the graphene multi-layer 210 to the core body 205. For example, prepreg material or dielectric glue can be used to affix the graphene multi-layer 210 to the core body 205 when heat and pressure under vacuum or controlled gas atmosphere are applied to the structure. In some embodiments, the lamination process may cause portions of the prepreg or dielectric glue 220 to enter the area around the edges of the graphene multi-layer 210, such that after application of the outer metallic layer(s) 217, the prepreg or dielectric glue 220 is disposed between the graphene multi-layer 210 and the metallic layer 217. In such embodiments, the graphene multi-layer 210 is electrically insulated from the at least one metallic layer 217 by the dielectric glue 220 or other dielectric material.

In other embodiments, the core body 205 may be a dielectric. For example, the core body 205 may, in some cases, comprise at least one of polyimide, polyester, polyurethane, bismaleimide triazine (BT), cyanate ester, fused silica, woven glass, fiberglass, microfiber glass, epoxy resin, phenol compounds, polytetrafluoroethylene (PTFE), low density polyethylene (LDPE), high density polyethylene (HDPE), polyethylene terephthalate (PET), thermoplastic polyurethane (TPU) or ceramic material.

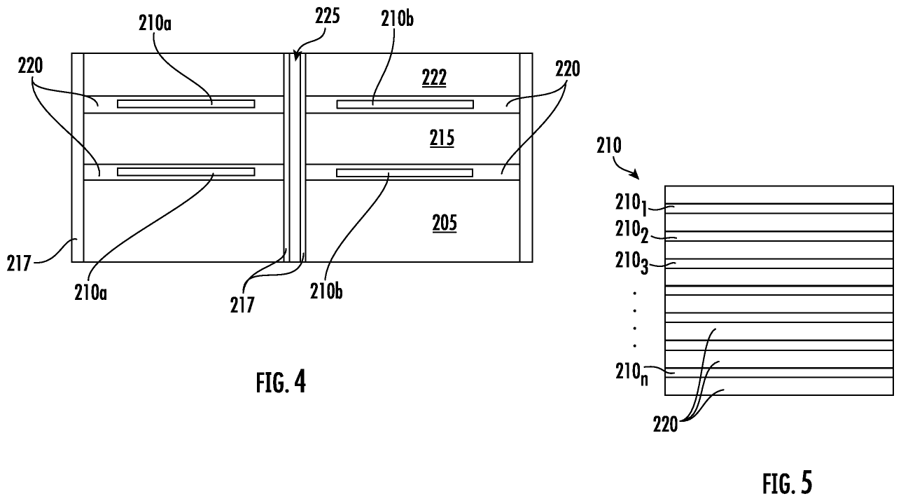

In some embodiments, the graphene multi-layer may be a first graphene multi-layer 210a, and the graphene integrated core may further comprise a second graphene multi-layer 210b. The second graphene multi-layer 210b may be spaced from the first graphene multi-layer 210a, such as when intervening layers (e.g., an intervening layer 215 and/or dielectric glue 220 or other dielectric/insulating layers) are present. Accordingly, in such cases, the first graphene multi-layer 210a may be in a different plane than the second graphene multi-layer 210b, as depicted in FIG. 3. In other embodiments, however, such as shown in FIG. 4, the first graphene multi-layer 210a may be in the same plane as the second graphene multi-layer 210b. This may be the case, for example, when a via 225 is disposed between the first graphene multi-layer 210a and the second graphene multi-layer 210b.

In still other embodiments, the graphene multi-layer 210 may be a plurality of graphene multi-layers, where each graphene multi-layer is spaced from adjacent graphene multi-layers, as shown in FIG. 5. The graphene multi-layers (e.g., graphene multi-layers 210₁, 210₂, 210₃ . . . , 210ₙ) may be laminated to each other, such as using a connecting layer 220 such as dielectric glue. In some cases, additional intermediate layers may be provided between adjacent graphene multi-layers 210₁-210ₙ, such as dielectric glue, prepreg, or metal layers or combinations thereof. The number of graphene multi-layers n may be selected based on the desired thermal conductivity for the particular PCB design, with additional graphene multi-layers (a larger n value) being selected when a higher thermal conductivity for the PCB is needed. The desired thickness of the PCB, the desired structural stability and process complexity, as well as the desired thermal conductivity for the circuit will also inform the number of graphene multi-layers. In some cases, n could be 1 layer to 10 layers to 100 layers or more. As the number of layers increases, the total thickness of the PCB will also increase.

In some cases, the graphene multi-layer 210 (or multiple graphene multi-layers 210) may be etched to achieve the graphene multi-layer length l_{g}, as described in greater detail below. In some embodiments, the graphene multi-layer 210 has a thickness in the range of approximately 1 nanometer (1 nm) to approximately two microns (2μ).

As will be understood by one skilled in the art in light of this disclosure, a number of different PCB designs (e.g., different numbers of layers, different materials, different thicknesses, different locations within the stack, different sizes and shapes, and different configurations for supporting various electrical components) may be made using embodiments described herein. In this regard, the figures referenced herein are simplified illustrations depicting the described embodiments for the purposes of explanation and do not necessarily reflect a particular design, but rather express the spirit of embodiments of the invention described herein.

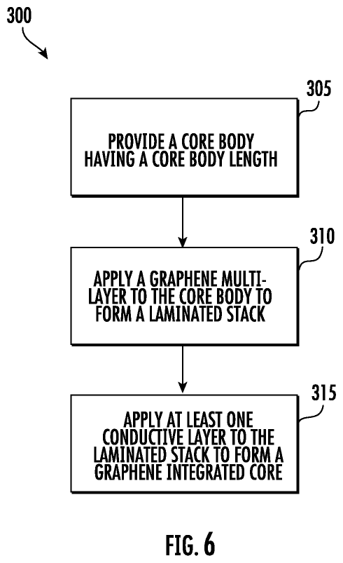

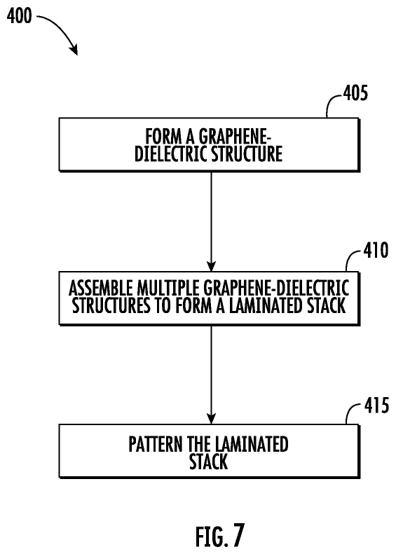

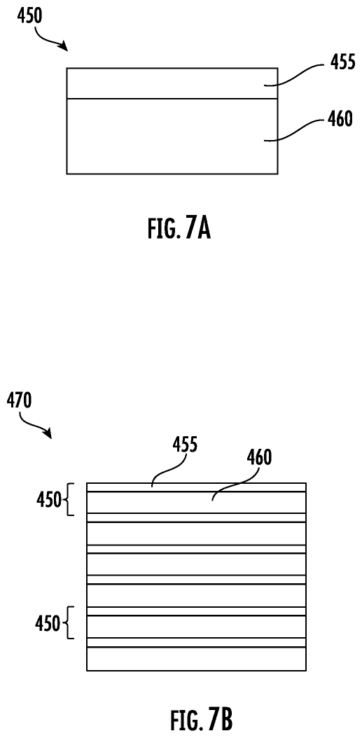

Turning now to FIGS. 6-7B, a method 300 of forming a graphene integrated core is described. With reference to FIG. 6, the method 300 may comprise providing a core body having a core body length at Block 305 and applying a graphene multi-layer to the core body to form a laminated stack at Block 310, as described above with reference to FIGS. 1A-5. As described above, the graphene multi-layer may have a graphene multi-layer length that is shorter than the core body length. The method further comprises applying at least one metallic layer (e.g., copper) to the laminated stack at Block 315. For example, the at least one metallic layer may be disposed as one of the layers within the graphene integrated core in some cases, whereas in other cases the method may comprise applying the at least one metallic layer to an outer surface of the graphene integrated core, such as using a plating process. As described above, the graphene multi-layer may be disposed within the graphene integrated core such that the graphene multi-layer is electrically insulated from the at least one metallic layer.

In this regard, the graphene multi-layer may be applied to the core body to form the graphene integrated core in a number of ways. With reference to FIG. 7, for example, in some embodiments, the graphene integrated core may be formed using a method 400 that includes forming a graphene-dielectric structure at Block 405, assembling multiple graphene-dielectric structures by stacking and laminating the graphene-dielectric structures to each other to form a laminated stack at Block 410, and patterning the laminated stack to form the desired electrical pathways at Block 415. In other embodiments, however, the graphene-dielectric structures may be patterned to for the desired electrical pathways prior to forming the laminated stack. The graphene-dielectric structure 450, shown in FIG. 7A, may comprise a graphene multi-layer 455 that is supported by a core body 460, such as prepreg or dielectric glue. In some cases, the graphene multi-layer may be laminated to a metal layer using a metallic adhesion layer, such as tin, antimony, lead, indium, or other soft metal. Moreover, in some embodiments, the graphene multi-layer 455 may be grown on a growth substrate (not shown), such as a nickel growth substrate, and the core body 460 may be laminated to a surface of the graphene multi-layer that is opposite the growth substrate. The growth substrate may be removed or released following the application of the core body. In some cases, the graphene multi-layer 455 may have a thickness of approximately one nanometer (1 nm) to approximately two micrometers (2p) or more.

Moreover, the number of graphene-dielectric structures 450 that are laminated to each other to form the laminated stack 470 (shown in FIG. 7B) may vary depending on the desired thermal conductivity for the PCB, among other considerations described above. Accordingly, the graphene multi-layer that is applied to the core body may be a plurality of graphene multi-layers, where each graphene multi-layer is spaced from adjacent graphene multi-layers, as shown in FIG. 7B. For example, two or three or up to ten or more graphene-dielectric structures 450 may be laminated to each other to form the laminated stack. As such, the plurality of graphene multi-layers may comprise n graphene multi-layers and n+1 connecting layers adjacent each graphene multi-layer. The connecting layers may be the prepreg layers or the dielectric glue layers described above and in connection with FIG. 7A or an additional dielectric interface material configured to affix adjacent graphene-dielectric structures 450 with respect to each other and/or with respect to adjacent structures (e.g., a substrate, not shown), such as through a lamination process. The connecting layers may thus secure the plurality of graphene multi-layers 455 with respect to each other upon lamination to form the laminated stack 470. As an example, in FIG. 7B, six graphene-dielectric structures 450 are laminated together to form the laminated stack 470. Once the laminated stack 470 is formed, the laminated stack may be patterned, as described above, according to techniques as would be understood by one skilled in the art in view of this disclosure (e.g., by wet etching). In other embodiments, however, each graphene-dielectric structure 450 may be patterned before forming the laminated stack 470.

For example, in accordance with some techniques, the process of drilling through the laminated stack in the location of the desired vias (where the hole is drilled having a diameter of D₁) will cause prepreg material in the location of the drilling to liquefy and enter the area of the drilled hole. The presence and/or extent of liquefication may depend on the aspect ratio of the thickness of the material drilled as compared to the diameter of the hole D₁. The liquefied prepreg will then re-solidify, and a second hole may be drilled in the center of the same hole, but at a smaller diameter D₂. As such, the difference between the diameters D₁ and D₂ will be filled with insulative prepreg material and will create a region of insulation between the edge of the graphene multi-layer and any metallic plating that is applied to the inside diameter D₂ of the smaller drilled hole, resulting in a graphene multi-layer having a shorter length than the core body length, such that the graphene multi-layer is disposed within the graphene integrated core in a way that electrically insulates the graphene multi-layer from a surrounding (e.g., plated) metallic layer applied on the inside surface of the via.

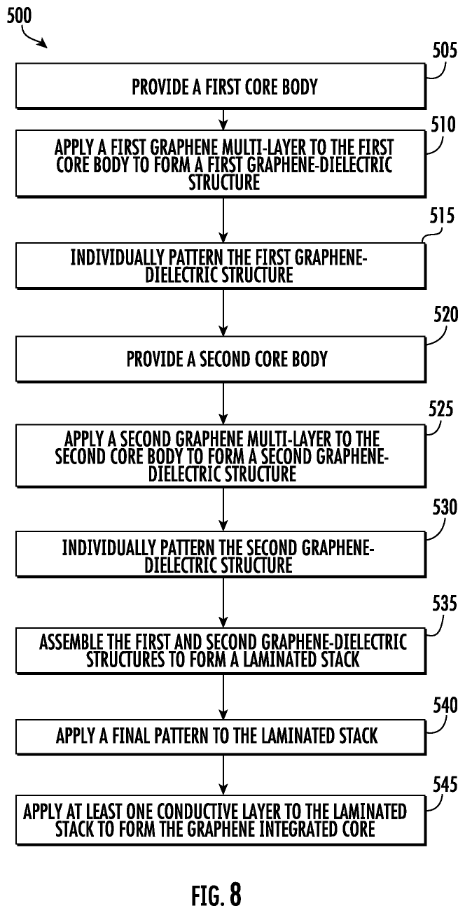

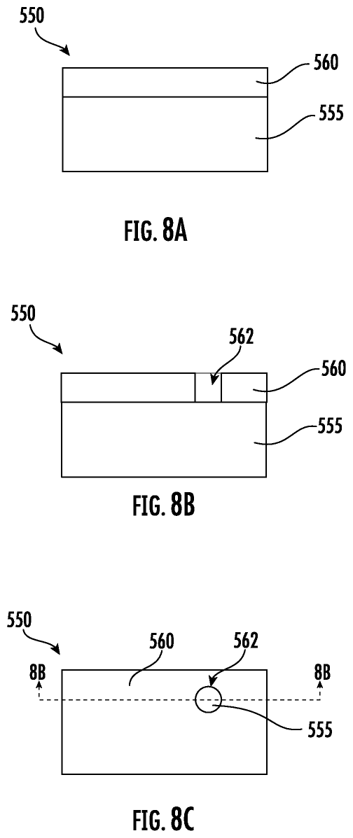

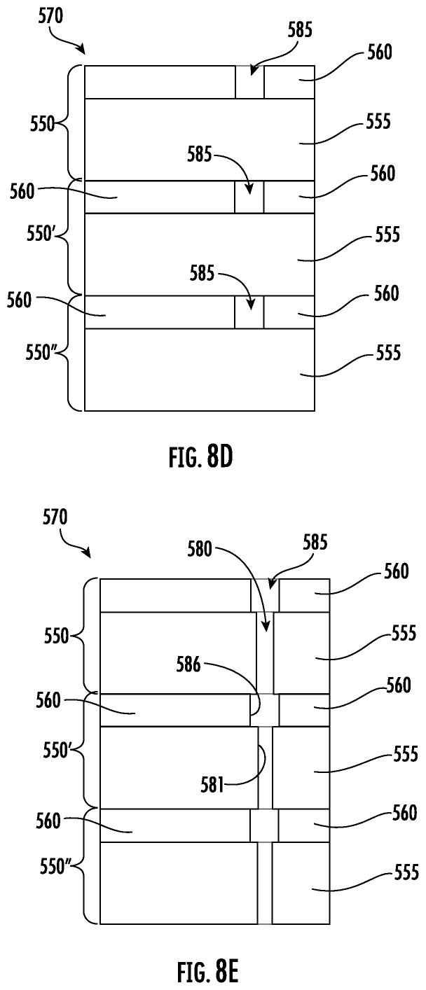

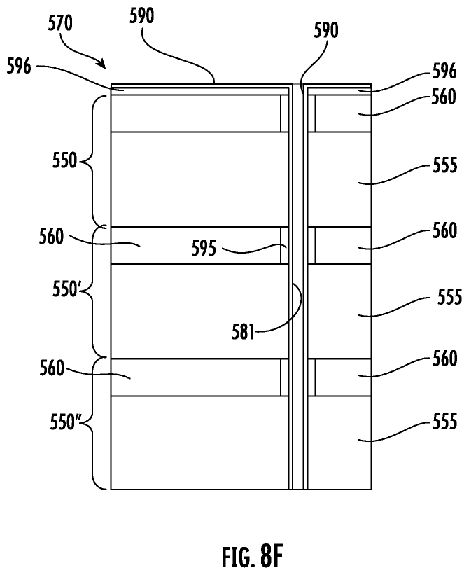

In other embodiments, with reference to FIG. 8, the graphene integrated core may be formed using a method 500 that includes providing a first core body at Block 505 and applying a first graphene multi-layer to the first core body at Block 510 to form a first graphene-dielectric structure. FIG. 8A is a side view of the graphene-dielectric structure 550 showing the core body 555 and the graphene multi-layer 560 applied thereto. As described above, the core body 555 may be a dielectric material, such as a prepreg layer or a dielectric glue. The graphene-dielectric structure 550 may be individually patterned to remove portions of the graphene multi-layer 560 in the desired locations corresponding to the electrical pathways that will be formed in the resulting graphene integrated core and eventual PCB. In FIGS. 8B and 8C, a side view and a top view, respectively, of the graphene-dielectric structure 550 is shown with a portion 562 of the graphene multi-layer 560 removed (e.g., corresponding to a location where a via will be disposed) to reveal the underlying core body material 555. As such, the method 500 of FIG. 8 includes individually patterning the first graphene-dielectric structure 550 by removing a portion of the first graphene multi-layer at Block 515.

At Blocks 520 and 525, respectively, the method 500 comprises providing a second core body and applying a second graphene multi-layer to the second core body to form a second graphene-dielectric structure. The second graphene-dielectric structure may also be individually patterned by removing a portion of the second graphene multi-layer at Block 530.

A desired number of graphene-dielectric structures (e.g., the graphene-dielectric structure 550 of FIGS. 8B and 8C) may be formed, each having a desired patterning applied to the graphene according to the patterning that is desired for the particular design of the graphene integrated core to be formed. At Block 535 of FIG. 8, the first graphene-dielectric structure and the second graphene-dielectric structure may be assembled (along with other graphene-dielectric structures to the extent required for the particular design of the eventual graphene integrated core) to form a laminated stack. In this regard, each graphene-dielectric structure may be properly aligned with adjacent graphene-dielectric structure(s) in consideration of the individual patterning that has been done on each graphene-dielectric structure. A cross-sectional view of the first through third graphene-dielectric structures 550, 550′, and 550″ forming the depicted laminated stack 570 is shown in FIG. 8D. In some cases, a connecting layer (not shown), such as a dielectric glue, may be applied to each graphene-dielectric structure during lamination to hold these structures in place with respect to each other and any adjacent structures.

Turning again to FIG. 8, the method 500 may further include applying a final pattern to the laminated stack at Block 540. With reference to FIG. 8E, the final pattern may be applied by drilling a hole 580 through the aligned hole formed by individual patterning of each graphene-dielectric structure 550, 550′, and 550″ that is smaller than the holes 585 formed in the graphene multi-layers 560 of each individual graphene-dielectric structure. In other words, because the through hole 580 has a smaller diameter than the individual holes 585 cut through the graphene multi-layers 560, the edge 586 of the holes 585 formed in the graphene multi-layers 560 are diametrically spaced from the edge 581 of the holes 580 formed in the core body 555, as shown.

The space between the edges 581, 586 may be filled with a dielectric material, such as the dielectric material used when laminating the graphene-dielectric structures 550, 550′, and 550″ together. For example, when a dielectric glue is applied to each graphene-dielectric structure during lamination, the dielectric glue, when heated and/or pressed, may move into the space past the edge 586, filling it. Thus, when the through hole 580 is formed, the through hole 580 cuts through the dielectric glue or other dielectric material filling the space past the edge 586. At Block 545 of the method 500 shown in FIG. 8, at least one metallic layer is applied to the laminated stack to form the graphene integrated core. As such, the dielectric glue or other dielectric material of the connecting layers may serve to further electrically insulate the graphene multi-layer from the metallic layer in the regions of the vias that are formed. For example, FIG. 8F shows the laminated stack 570 after application of a metallic layer 590 to an inner surface of the via formed by the through hole 580, with the dielectric glue 595 electrically isolating the graphene multi-layers 560 from the metallic layer 590 in the resulting graphene integrated core. As will be understood by those skilled in the art in view of this disclosure, additional dielectric layers (such as layers 596) may be incorporated to form the graphene integrated core.

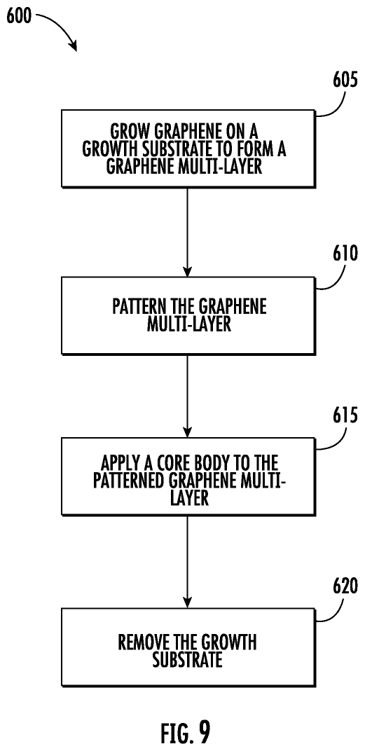

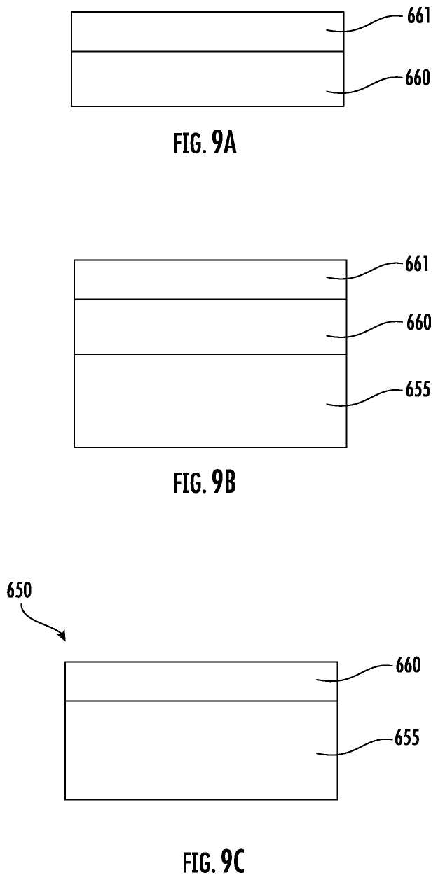

Turning now to FIG. 9, another embodiment of a method 600 of forming the graphene integrated core is shown. Embodiments of the method 600 include growing graphene on a growth substrate, such as nickel, to form a graphene multi-layer at Block 605. A graphene multi-layer 660 grown on a growth substrate 661 is shown in FIG. 9A. At Block 610 of FIG. 9, the graphene multi-layer is patterned, and at Block 615 a core body is applied to the patterned graphene multi-layer. For example, the core body 655 may be applied to an opposite surface of the graphene multi-layer 660 from the growth substrate 661, as shown in FIG. 9B, such as by pressing the graphene multi-layer and the core body together. The growth substrate may then be removed at Block 620 of FIG. 9 to form a graphene-dielectric structure. The resulting graphene-dielectric structure 650 shown in FIG. 9C may thus be similar to the graphene-dielectric structure 450 of FIG. 7A or the graphene-dielectric structure 550 of FIG. 8A. In some cases, the graphene may be grown in a particular configuration (e.g., a particular size and/or shape, such as circular), depending on the desired circuit design.

As described above, a desired number of graphene-dielectric structures may be formed, each having a desired patterning applied to the graphene according to the patterning that is desired for the particular design of the resulting graphene integrated core, and the process of forming the graphene integrated core may continue as shown and described above with respect to Blocks 410-415 of FIG. 7 or Blocks 535-545 of FIG. 8. For example, the graphene-dielectric structures may be assembled (e.g., stacked and laminated) to form a laminated stack (Block 535 of FIG. 8); a final pattern may be applied to the laminated stack (Block 540 of FIG. 8); and at least one metallic layer may be applied to the laminated stack to form the graphene integrated core (Block 545 of FIG. 8). As described above with respect to the embodiment shown and described in FIGS. 8-8F, a dielectric glue or other dielectric material used in the process of forming the laminated stack may serve to electrically insulate the graphene multi-layers from the metallic layer(s) in the regions of the vias that are formed. Embodiments of the method described with respect to FIG. 9 may have the advantage of allowing patterning to be applied to the graphene multi-layer without risking damage to or erroneous patterning of the core body, as the graphene multi-layer is patterned prior to joining the graphene multi-layer to the core body.

FIGS. 7, 8, and 9 are flowcharts providing example methods 400, 500, 600 for forming a graphene integrated core in accordance with one or more embodiments of the present invention. It will be understood that each block of the flowcharts, and combinations of blocks in the flowcharts, may be implemented by various means. In some example embodiments, certain ones of the operations herein may be modified or further amplified as described below. Moreover, in some embodiments additional optional operations may also be included. It should be appreciated that each of the modifications, optional additions, or amplifications described herein may be included with the operations herein either alone or in combination with any others among the features described herein. The operations illustrated in FIGS. 7, 8, and 9 may, for example, incorporate additional steps, such as to incorporate additional materials and/or layers (e.g., dielectrics, metals, graphite, and/or combinations thereof) as well as electronic components, traces, solder, etc. to form the PCB, and the operations may be carried out in a different order than that depicted in the figures in some cases. Moreover, one skilled in the art in view of this disclosure will understand that the patterning of individual graphene multi-layers may not necessarily be the same as the other graphene multi-layers in the same circuit or circuit board (e.g., the graphene multi-layers may have different patterning applied), depending on the desired product and/or application.

Many modifications and other embodiments of the present inventions set forth herein will come to mind to one skilled in the art to which these inventions pertain having the benefit of the teachings presented in the foregoing descriptions and the associated drawings. Therefore, it is to be understood that the present inventions are not to be limited to the specific embodiments disclosed and that modifications and other embodiments are intended to be included within the scope of the appended claims. Moreover, although the foregoing descriptions and the associated drawings describe example embodiments in the context of certain example combinations of elements and/or functions, it should be appreciated that different combinations of elements and/or functions may be provided by alternative embodiments without departing from the scope of the appended claims. In this regard, for example, different combinations of elements and/or functions than those explicitly described above are also contemplated as may be set forth in some of the appended claims. Although specific terms are employed herein, they are used in a generic and descriptive sense only and not for purposes of limitation.

1. A method of forming a graphene integrated core comprising:
providing a core body having a core body length;
applying a graphene multi-layer to the core body to form a laminated stack, wherein the graphene multi-layer has a graphene multi-layer length that is shorter than the core body length; and
applying at least one conductive layer to the laminated stack,
wherein the graphene multi-layer is disposed within the graphene integrated core such that the graphene multi-layer is electrically insulated from the at least one conductive layer.

2. The method according to claim 1, wherein applying a graphene multi-layer to the core body to form a laminated stack comprises forming a graphene-dielectric structure, wherein the method further comprises assembling multiple graphene-dielectric structures to form the laminated stack.

3. The method according to claim 2, wherein assembling multiple graphene-dielectric structures comprises applying a connecting layer between adjacent graphene-dielectric structures.

4. The method according to claim 3, wherein at least a portion of the connecting layer is disposed between the graphene multi-layer and the at least one conductive layer.

5. The method according to claim 2 further comprising patterning the laminated stack.

6. The method according to claim 1, wherein applying a graphene multi-layer to the core body to form a laminated stack comprises:
applying a first graphene multi-layer to a first core body to form a first graphene-dielectric structure;
individually patterning the first graphene-dielectric structure;
applying a second graphene multi-layer to a second core body to form a second graphene-dielectric structure;
individually patterning the second graphene-dielectric structure;
assembling the first and second graphene-dielectric structures to form the laminated stack; and
applying a final pattern to the laminated stack.

7. The method according to claim 1, wherein applying a graphene multi-layer to the core body to form a laminated stack comprises:
growing graphene on a growth substrate to form the graphene multi-layer;
patterning the graphene multi-layer;
applying the core body to the patterned graphene multi-layer; and
removing the growth substrate.

8. The method according to claim 1, wherein the graphene multi-layer is a plurality of graphene multi-layers, wherein each graphene multi-layer is spaced from adjacent graphene multi-layers.

9. The method according to claim 8, wherein the plurality of graphene multi-layers comprises n graphene multi-layers and n+1 connecting layers adjacent each graphene multi-layer, wherein the connecting layers secure the plurality of graphene multi-layers with respect to each other.

10. The method according to claim 1 further comprising defining a via through the graphene integrated core, wherein applying the at least one conductive layer to the laminated stack comprises applying the at least one conductive layer to an inner surface of the via.

11. A graphene integrated core comprising:
a core body having a core body length;
a graphene multi-layer applied to the core body to form a laminated stack, wherein the graphene multi-layer has a graphene multi-layer length that is shorter than the core body length; and
at least one conductive layer,
wherein the graphene multi-layer is disposed within the graphene integrated core such that the graphene multi-layer is electrically insulated from the at least one conductive layer.

12. The graphene integrated core according to claim 11, wherein the graphene multi-layer is a first graphene multi-layer, the graphene integrated core further comprising a second graphene multi-layer, wherein the second graphene multi-layer is spaced from the first graphene multi-layer.

13. The graphene integrated core according to claim 12, wherein the first graphene multi-layer is in a different plane than the second graphene multi-layer.

14. The graphene integrated core according to claim 12, wherein the first graphene multi-layer is in the same plane as the second graphene multi-layer.

15. The graphene integrated core according to claim 11, wherein the graphene multi-layer and the core body form a graphene-dielectric structure, wherein the graphene integrated core further comprising multiple graphene-dielectric structures having a connecting layer disposed between adjacent graphene-dielectric structures.

16. The graphene integrated core according to claim 15, wherein at least a portion of the connecting layer is disposed between the graphene multi-layer and the at least one conductive layer.

17. The graphene integrated core according to claim 11, wherein the at least one conductive layer is disposed on an outer surface of the graphene integrated core.

18. The graphene integrated core according to claim 17, wherein the at least one conductive layer is disposed on an inner surface of a via formed through the graphene integrated core.

19. The graphene integrated core according to claim 11, wherein the core body comprises at least one of polyimide, polyester, polyurethane, bismaleimide triazine (BT), cyanate ester, fused silica, woven glass, fiberglass, microfiber glass, epoxy resin, phenol compounds, polytetrafluoroethylene (PTFE), low density polyethylene (LDPE), high density polyethylene (HDPE), polyethylene terephthalate (PET), thermoplastic polyurethane (TPU), or ceramic material.

20. The graphene integrated core according to claim 11, wherein the graphene multi-layer has a thickness in the range of approximately one nanometer to approximately two microns.
